(19) United States
(12) Patent Application Publication
(10) Pub. No.: US 2015/0144063 A1
(43) Pub. Date: May 28, 2015

(54) DEVICE FOR A VACUUM AND FOR TRANSMITTING OR ENABLING A MOVEMENT

(71) Applicant: Max-Planck-Gessellschaft zur Förderung der Wissenscaften e.V., Munich (DE)

(72) Inventor: Wolfgang Braun, Bietigheim-Bissingen (DE)

(73) Assignee: Max-Planck-Gessellschaft zur Förderung der Wissenscaften e.V., Munich (DE)

(21) Appl. No.: 14/381,806

(22) PCT Filed: Feb. 27, 2013
(86) PCT No.: PCT/EP2013/000580

§ 371 Date: Feb. 1, 2015

(30) Foreign Application Priority Data
Feb. 29, 2012 (DE) 10 2012 004 082.2

(51) Int. Cl. F16H 19/04; C23C 14/24; C30B 23/02; F16H 55/17

(52) U.S. Cl. CPC F16H 19/04; F16H 55/17; C23C 14/24; C30B 23/02
USPC 118/726; 137/334; 74/422; 74/89.17

(57) ABSTRACT

A device for movement transmission, torque transmission, force transmission and/or enabling movement can form a gear and/or guidance mechanism and be used in a vacuum. The device includes at least one notch/engagement part mechanism, which is formed by at least one notch and at least one engagement part. The device further includes at least two contact surfaces, at least one contact surface being able to roll along the other contact surface.

The invention relates to an apparatus in particular for transmission of movement, transmission of force/transmission of torque and/or enabling movement, preferably for forming a link, a gear, a bearing, a guide or the like. The apparatus is preferably suitable for a vapour-deposition apparatus for vapour-depositing an evaporation material on a substrate, in particular suitable for molecular beam epitaxy, and preferably suitable for use in a vacuum or even an ultrahigh vacuum.

Various embodiments of vapour-deposition apparatuses forming an ultrahigh vacuum for vapour-depositing an evaporation material on a substrate are known in the prior art. An exemplary embodiment is e.g. described in DE 10 2007 012 370 A1. Conventional vapour-deposition apparatuses usually comprise a coating chamber or process chamber and additional auxiliary chambers, one of which can, for example, be formed as a loading chamber. The chambers are connected by a transfer tunnel, which can be closed by a vacuum valve. The chambers are evacuated by vacuum pumps for generating a vacuum, in particular a high vacuum. A workpiece to be provided with a vapour-deposited coating is introduced via a loading flap into the loading chamber following an aeration of the loading chamber after which the loading flap is closed and the loading chamber is evacuated. Once a sufficiently low pressure is obtained, the workpiece is heated to a low temperature in the loading chamber in order to heat away surface contamination such as, for example, water or moisture. After this, the vacuum valve is opened and the workpiece is transferred to the process chamber using a transfer apparatus. There, it is placed onto a rotatable heating apparatus, the substrate manipulator, where it is heated and rotated for the coating. The flow of the evaporation material from the evaporation furnace is interrupted or released by a closure part in front of the evaporation furnace. Following the vapour deposition, the rotation is stopped, the specimen is cooled and is transferred back into the loading chamber from where it can be removed after the aeration of the loading chamber. It is evident that different movement processes are required in a vacuum, for example rotational movements, such as, for example, for workpiece rotation, at least approximately linear movements, such as, for example, for evaporator cell closure, at least approximately linear movements over relatively long distances, such as are required, for example, for the transfer of the workpiece/specimen, etc.

In vacuum technology, in particular ultrahigh vacuum technology, no organic substances can be used in contact with the vacuum if one wants to achieve extremely low base pressures (for example of 1.0×10⁻¹⁰ mbar). This is in particular true having regard to the simultaneous occurrence of high temperatures (for example above 500° C.) such as, for example, are required during vapour-deposition processes. For this reason, no organic lubricants are available for moving parts. The choice of materials is limited to refractory metals and ceramics with low vapour pressure. For linear movements, for example, a sliding movement of a hard, smooth-polished part, for example a stainless steel push rod, is frequently used in a softer sleeve, for example made of bronze. However, combinations of this kind usually have a rather short life because the softer material is rapidly eroded due to the absence of lubrication. If the surfaces are also coated with evaporated material, the smooth part often becomes rough and the resulting increased friction further reduces the lifetime thereof. Rotational movements, for example, generally require an axis with a finite diameter. Thus, also in this instance, friction occurs between the two surfaces. Normally, ball bearings are used for this application in a vacuum, but these only avoid the problem at a first glance in that the sliding of two parts is replaced by a rolling movement. However, the balls have to be maintained in their position by ball-bearing cages which in turn rub against the balls in a planar manner and result in a less than ideal service life. Even cage-free ball bearings exhibit this deficiency, as in this instance the balls laterally rub against one another at twice the rolling speed. For this reason, solid-based lubricants are frequently used, but as minute particles these can contaminate the vacuum processes and only achieve a prolongation of the service life since the movement causes them to work themselves out of the bearings.

In view of the above, it is evident to those skilled in the art from this disclosure that a requirement exists to solve or overcome the above-described problems or disadvantages. The present invention addresses this need in the prior art and other requirements, which will become apparent to those skilled in the art from this disclosure.

The object arising from the above description can be achieved in particular with the features of the independent claim. However, the invention is not limited to embodiments that remedy all of the problems or disadvantages of the prior art named in the foregoing. On the contrary, the invention also claims general protection for the exemplary embodiments described in the following.

According to the invention, an apparatus is provided which is in particular suitable for transmission of movement (advantageously a low-friction and/or lubricant-free transmission of movement), transmission of force, transmission of torque and/or enabling movement or the like. Preferably, the apparatus is used to form a gear mechanism and/or guide mechanism (advantageously of low-friction and/or lubricant-free) or the like.

The apparatus is particularly suitable for a vacuum system, in particular an ultrahigh vacuum system, preferably for a vapour-deposition apparatus for the vapour deposition of an evaporation material onto a substrate and/or a device for molecular beam epitaxy.

The apparatus is preferably suitable for use in an ultrahigh vacuum (for example≦1.0×10⁻⁸ mbar, ≦1.0×10⁻⁹ mbar or even<1.0×10⁻¹⁰ mbar) and/or under high temperatures (for example>300° C., >400° C., >500° C. or >600° C.). The apparatus can expediently comprise means to generate the aforementioned vacuum and/or the aforementioned temperature.

The apparatus preferably comprises at least one notch-engagement part mechanism, which is formed by at least one notch and at least one engagement part.

In particular, in addition to the at least one notch-engagement part mechanism, the apparatus additionally comprises at least two contact surfaces, wherein at least one contact surface can roll along the other contact surface, which is then expediently formed as a running surface.

The at least two contact surfaces are in particular used for load bearing/load transmission perpendicular to the rolling direction.

The apparatus expediently results in at least one of the following advantages:
a uniform, for example exactly linear, movement can be achieved
shocks or vibrations can be avoided
low wear due to a continuous sequence of contact lines with ‘a cutting-edge or engagement-part angle of zero’
decoupling of the form of movement from the size and shape of the gear tooth guidance. This point is in particular significant with respect to production technology because it is now possible to choose a few large teeth, which are simple and hence inexpensive to produce. It is also now possible to select the gear-tooth period and hence the height of the engagement parts or teeth as relatively large without impairing the smooth running of the apparatus. Thus, it is also possible, for example, to dimension the clearance of an emergency bearing and hence the production tolerances of connected parts more generously. The apparatus is consequently also not susceptible to failure due to distortion, which may occur, for example, due to thermal stress.

The at least one engagement part is formed to enter the at least one notch. It is for example possible within the scope of the invention for at least one notch to be fixed and at least one engagement part to be moveable and for penetration to occur by means of the movement of the engagement part toward the notch-engagement part. However, within the scope of the invention it is also alternatively or additionally possible that at least one notch is moveable and at least one engagement part is fixed and for the entering thereof to occur by means of the movement of the notch toward the notch-engagement part. In the context of the invention, it is also possible that both of the at least one notch and the at least one engagement part are moveable. The at least one engagement part is consequently expediently formed for the active and/or passive entrance into the at least one notch.

In the context of the invention, the notch-engagement part mechanism can in particular be formed as a gear mechanism, for example as gear wheel/gear rack construction, gear wheel/gear wheel construction, gear rack/gear wheel/gear rack construction or even as a planetary gear. The notch-engagement part mechanism can, for example, be a conventional gear mechanism known from the prior art. However, the notch-engagement part mechanism can also, for example be formed according to DE 10 2011 013 245 so that the content of this document is entirely incorporated into the present disclosure.

The notch-engagement part mechanism preferably serves for reproducible positioning and/or to prevent tilting or tipping of a moveable part expediently relative to a fixed part of the apparatus. The notch-engagement part mechanism is alternatively or additionally in particular serves for the lateral guidance of a moveable part expediently relatively to a fixed part of the apparatus. The guidance and/or the prevention of tilting/tipping is preferably expediently achieved by rolling and/or discrete operative contact between a fixed part and a moveable part of the apparatus between a lateral guide section of a fixed part and at least one engagement part of a moveable part. The discrete operative contact could, for example, be substantially point-like or edge-shaped.

It is possible that at least one notch-engagement part mechanism is laterally formed, for example directly next to the two contact surfaces.

It is also possible that the two contact surfaces are formed between at least two notch-engagement part mechanisms, which are, for example, spaced apart from one another transverse to the rolling direction. This, for example, makes it possible that the external notch-engagement part mechanisms experiences an expediently maximum guide torque and/or an expediently maximum lateral guide force and hence minimal wear due to internal guides.

Preferably, the at least one notch comprises a notch base and the at least one engagement part preferably comprises a front end section.

It is possible that a contact surface is at least aligned approximately flush with at least one notch base. Here, the contact surface can, for example, transition directly into the at least one notch base or at least be insignificantly spaced apart from the at least one notch base. Consequently, the radius of the contact surface preferably substantially corresponds to the root circle of the gear teeth or notch(es). In this way, the contact surface is expediently in contact with at least one notch base in its notional continuation.

It is likewise possible that the other contact surface is aligned at least approximately flush with at least one front end section. In this connection the contact surface can, for example, pass directly into at least one front end section or at least be insignificantly spaced apart from at least one front end section. In this way the contact surface is expediently in contact with at least one front end section in its notional continuation.

Having regard to a particularly preferred embodiment, it is possible that a contact surface is aligned at least approximately flush with at least one notch base and during the rolling to be temporarily aligned at least approximately flush with at least one front end section, and/or the other contact surface to be aligned at least approximately flush with respect to at least one front end section and during the rolling to be temporarily aligned at least approximately flush with respect to at least one notch base.

Preferably, at least one notch base and at least one front end section are formed for a moveable and/or contacting operative connection to one another. With this embodiment, it is possible that at least one front end section is supported on at least one notch base or vice versa. With this embodiment, the at least one notch base is preferably formed at a moveable part and the at least one engagement part is preferably formed at a fixed part.

Alternatively or additionally, it is possible that at least one notch base and at least one front end section are formed so that they are expediently spaced apart from one another in the radial direction, even if the corresponding engagement part is positioned as completely as possible in the corresponding notch and thus preferably no contacting operative connection results, even with a maximum penetration. Having regard to this embodiment, the at least one notch base is preferably formed at a fixed part and the at least one engagement part is preferably formed at a moveable part.

It is possible that the at least one notch-engagement part mechanism is formed by a plurality of notches, which expediently each comprise a notch base, and a plurality of engagement parts, which expediently each comprise a front end section.

The notch-engagement part mechanism can in particular be formed such that a contacting operative connection of a notch base-end section pair front end section passes indirectly or directly into a notch base-front end section pair, whose notch base and front end section remain spaced apart from one another, even if the corresponding engagement part is positioned as completely as possible in the corresponding notch or vice versa. This expediently makes it possible that, in the rolling direction, a contacting operative connection only forms between each second notch base and each second front end section and/or the intermediate notch base(s) and front end section(s) remain spaced apart from one another, even if a corresponding engagement part is positioned as completely as possible in a corresponding notch.

It is possible that a contact surface comprises at least one side section for lateral guidance of at least one engagement part expediently along the rolling direction. The lateral guidance takes place preferably by means of a rolling and/or temporary operative contact between the side section and the at least one engagement part. The operative contact can preferably be formed as discrete, in particular substantially point-like or edge-shaped, for example in dependence on the skew configurations of the side section described below and on the engagement part to be guided.

The side section is preferably exposed by one or more notches. The operative contact is preferably created when an engagement part to be guided is positioned as completely as possible in a corresponding notch.

The side section is suitably laid open at a fixed part and the at least one guided engagement part is expediently formed at a moveable part.

It is possible that the at least one side section is expediently bevelled with respect to the vertical at one or more sides and/or that at least one engagement part is expediently bevelled with respect to the radial direction (for example conical) at one or more sides.

In particular, the side section and the at least one engagement part are bevelled such that, for lateral guidance, a discrete (for example substantially point-like or edge-shaped) operative contact is achieved between the side section and the at least one engagement part.

Preferably, the side section and the at least one engagement part have different angles of skew, wherein the angle of skew of the side section is preferably larger than the angle(s) of skew of an engagement part to be guided.

It is possible that a contact surface is level at least in sections (for example, to extend substantially in a straight line) and for the other contact surface to have a curved cross section, preferably circular or of arc-shape, at least in sections. The contact surface can thus, for example, be cylindrical or in the shape of a circular cylinder. It is also possible that two contact surfaces have a curved cross section, for example for constructions of the gear wheel/gear wheel type or constructions having regard to which a curved contact surface can roll along another curved contact surface. Gear ring constructions are also possible, for example to form a planetary gear. Embodiments are even possible, with which a contact/running surface has a helical shape or cone shape.

Preferably, a plurality of notches and engagement parts are formed at a moveable part and a plurality of notches and engagement parts are formed at a fixed part. It is possible that the notches of the moveable part are configured differently from the notches of the fixed part and/or that the engagement parts of the moveable part are configured differently than the engagement parts of the fixed part.

It is possible that at least one engagement part comprises two differently configured edge sections and/or for at least one notch to comprise two differently configured edge sections. In this case, the at least one notch and/or the at least one engagement part is/are thus formed differently in the forward rolling direction and the backward rolling direction.

The apparatus can comprise a functional part, which can preferably be moved (for example displaced, rotated and/or swivelled) by means of the at least one notch-engagement part mechanism and/or the at least two contact surfaces such that it can expediently be conveyed from a starting position into a target position in a targeted manner and vice versa.

The functional part can, for example, be moved, in particular displaced, by at least 30 mm, 40 mm, 50 mm, 60 mm, 80 mm, 90 mm, 100 mm, 110 mm or 120 mm.

It is possible that the apparatus comprises a means for operating that is formed in order to drive the functional part directly or indirectly. The means for operating is preferably formed such that it can move the functional part from the outside through a chamber wall, by means of suitable remotely-acting forces and/or without it coming into contact with the functional part and/or without it requiring a physical penetration of the chamber wall to this end. Alternatively or additionally, the means for operating is preferably formed to generate a contact pressure between the at least two contact surfaces, whereby, for example, the at least two contact surfaces and/or the at least one notch-engagement part mechanism is/are held together. The contact pressure is preferably generated from the outside through a chamber wall, by means of suitable remotely-acting forces and/or without requiring a physical penetration of the chamber wall. The remotely-acting forces are in particular magnetic, electromagnetic or electrostatic forces.

The means for operating can be magnetic and the apparatus or the functional part assigned to the apparatus can be magnetisable or vice versa. However, it is also possible that the means for operating and the apparatus or the functional part assigned to the apparatus are magnetic. It is also possible, for example, that electromagnetic fields, electrostatic fields and/or the gravitational force are used. The fields can be (in particular electromagnetic) travelling fields. Thus, the means for operating in particular works by means of remotely-acting forces.

Preferably, the means for operating are motor driven. The suitably motor-drivable means for operating in particular enable automated motional sequences of e.g. the functional part. Having regard to this embodiment, the apparatus thus preferably also comprises a motor device to drive the means for operating.

It is possible that the apparatus is arranged in a chamber bounded by a chamber wall with the exception of the means for operating. The means for operating is preferably arranged outside of the chamber and/or is formed to carry out a function within the chamber from the outside by means of a remotely-acting force acting through the chamber wall, for example—as suitably described above—to convey the functional part from a starting position into a target position and/or to generate the contact pressure between the at least two contact surfaces. The means for operating can act on the functional part directly or indirectly, for example via a coupling piece.

The chamber is preferably a vacuum chamber or even an ultrahigh vacuum chamber. The apparatus can, for example, comprise means for generating a vacuum or even means for generating an ultrahigh vacuum in the chamber and/or means for heating the chamber (for example to above 400° C., 500° or 600° C.). The means for heating the chamber can be arranged inside or outside of the chamber.

The apparatus also preferably comprises at least one emergency holder, which ensures that the at least two contact surfaces and/or the at least one notch-engagement part mechanism does not become excessively loose, in particular when the means for operating is removed or acts in a non-satisfactory manner in some other way. The emergency holder can be configured such that it permits a certain loosening of the apparatus, in particular of the at least two contact surfaces and/or of the at least one notch-engagement part mechanism, but prevents an excessive loosening, which would, for example, result in blocking, tilting or even disintegration.

In a preferred embodiment, the functional part comprises a closure apparatus for suitably opening and closing an opening or a transfer apparatus for suitably transferring (for example moving to and fro) specimens or substrates or workpieces generally.

It should be mentioned that at least one engagement part preferably tapers towards its front end section and thus can preferably have a cutting-edge or a sharp-angled shape. However, it is also possible that at least one engagement part is formed, for example, of arcuate shape or substantially in a rectangular or trapezoidal shape so that, within the scope of the invention, the front end section can, for example, also be formed by an approximately arcuate shape or even a planar surface or any other suitable configuration. However, at least one engagement part is preferably formed as a cutting edge. Within the scope of the invention, the notch can also have any suitable configuration.

It should also be mentioned that the contact between the at least two contact surfaces is preferably not cancelled by the notch-engagement part mechanism and thus a contact is always provided between the two contact surfaces, for example between the starting position and the target position.

The invention was described in the foregoing partly with reference to an engagement part and a notch. However, it is evident that the invention in particular also comprises a notch-engagement part mechanism formed by a plurality of notches and a plurality of engagement parts. Thus, the description provided in the foregoing, partly with reference to an engagement part and a notch, also correspondingly applies to the embodiment according to the invention having a plurality of notches and a plurality of engagement parts. The same applies to embodiments with more than two contact surfaces, for example one fixed part and more than one moveable part.

The invention also comprises a vacuum system, in particular a device for molecular beam epitaxy and/or vapour deposition of an evaporation material onto a substrate comprising an apparatus as described herein. The vacuum system can, for example, be an ultrahigh vacuum system, which is expediently suitable for generating an ultrahigh vacuum of preferably≦1.0×10⁻⁸ mbar, ≦1.0×10⁻⁹ mbar or even≦1.0×10⁻¹⁰ mbar. Alternatively or additionally, the vacuum system can be suitable for generating a temperature of, for example, more than 300° C., more than 400° C., more than 500° C. or even more than 600° C.

The vacuum system preferably comprises a chamber and expediently means for generating the aforementioned vacuum in the chamber. It is also possible that a heating apparatus for heating the chamber to the aforementioned temperatures is provided. The chamber is expediently bounded by a chamber wall.

The above-described features and preferred exemplary embodiments of the invention can be combined with one another in an arbitrary desired manner. Other advantageous developments of the invention are disclosed in the subordinate claims or may be derived from the following description of preferred embodiments of the invention in conjunction with the accompanying drawings.

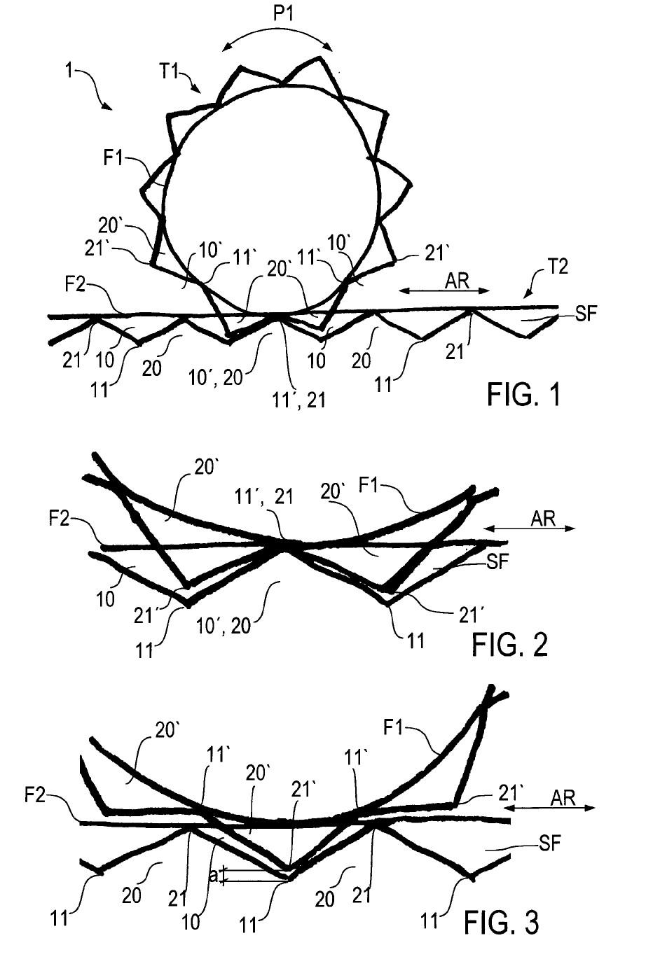

FIG. 1 shows a schematic side view of an apparatus according to one embodiment of the invention,

FIG. 2 shows an enlarged schematic representation of a part of the apparatus of FIG. 1,

FIG. 3 shows an enlarged schematic representation of a part of the apparatus of FIG. 1

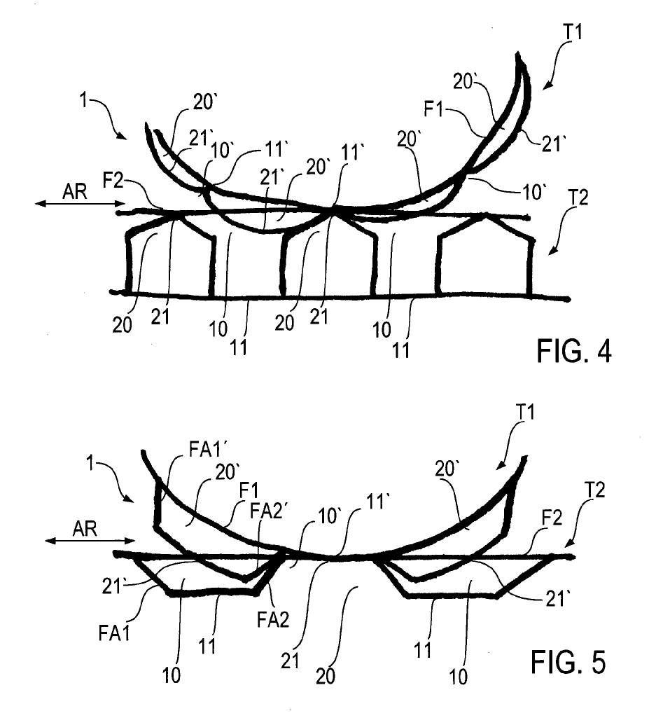

FIG. 4 shows a schematic side view of an apparatus according to another embodiment of the invention,

FIG. 5 shows a schematic side view of an apparatus according to yet another embodiment of the invention,

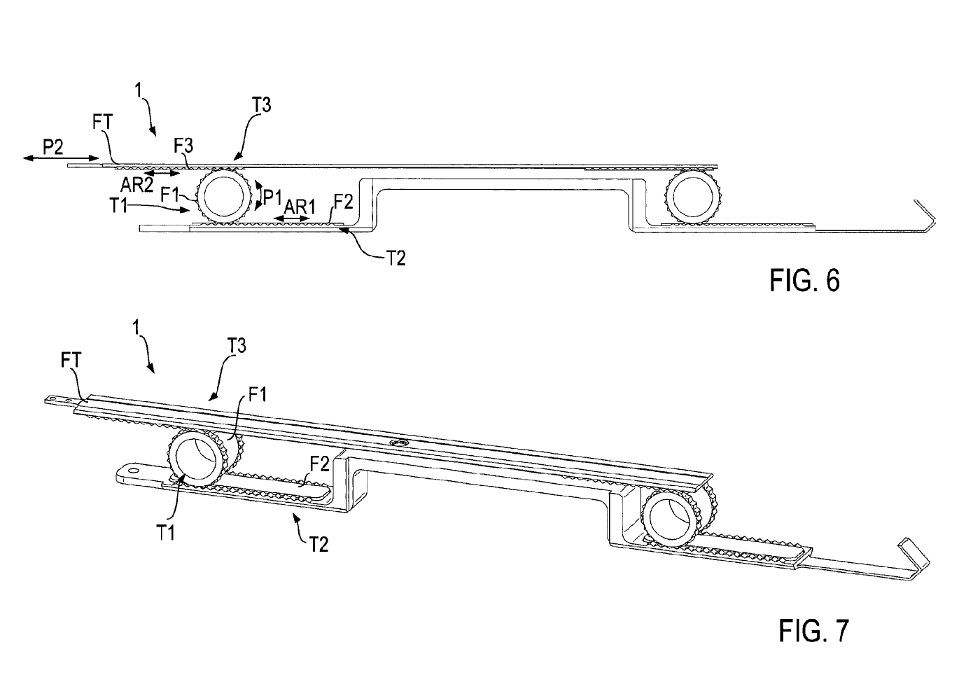

FIG. 6 shows a side view of an apparatus according to yet another embodiment of the invention,

FIG. 7 shows a perspective view of the apparatus of FIG. 6,

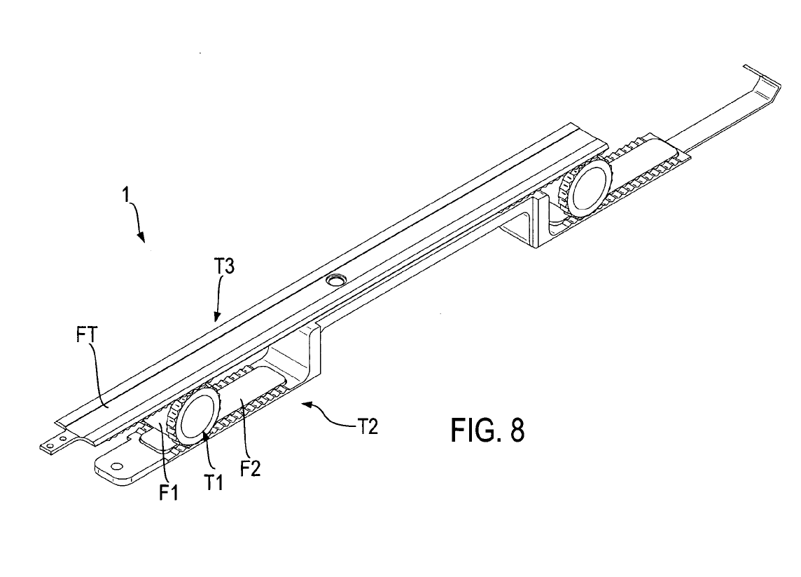

FIG. 8 shows another perspective view of the apparatus of FIG. 6,

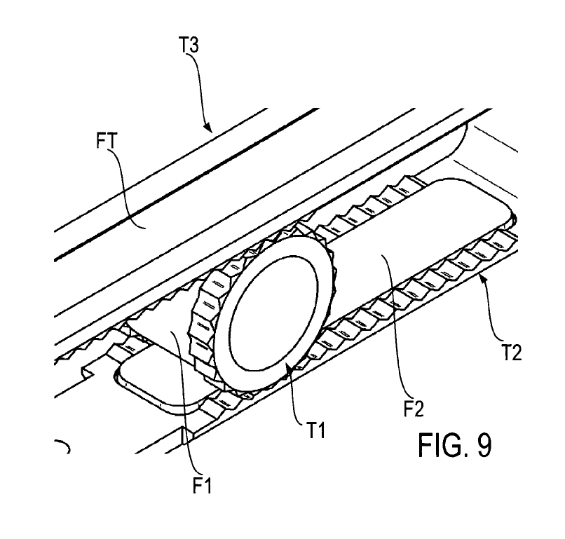

FIG. 9 shows an enlarged perspective representation of a part of the apparatus of FIG. 6,

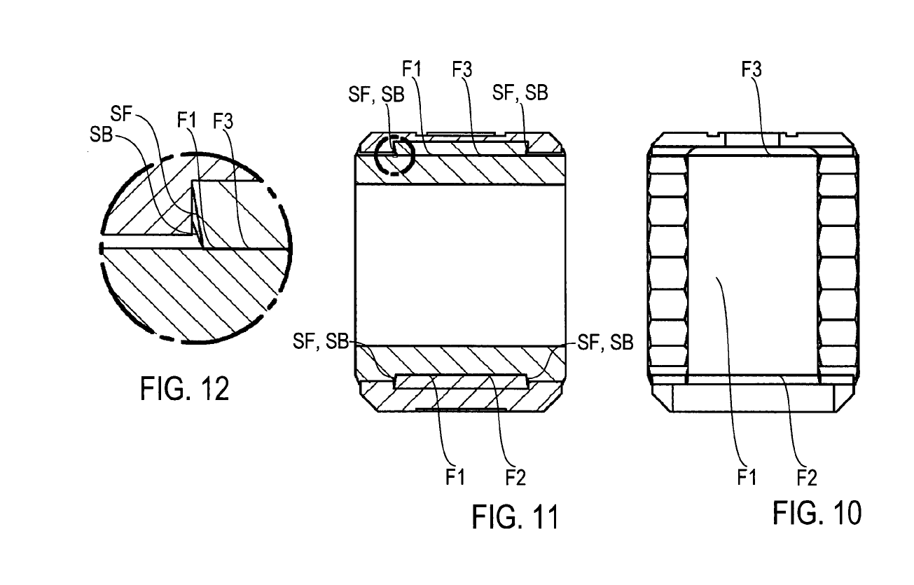

FIG. 10 shows a front view of the apparatus of FIG. 6,

FIG. 11 shows a sectional view of the apparatus of FIG. 6,

FIG. 12 shows an enlarged representation of the section marked in FIG. 11, and

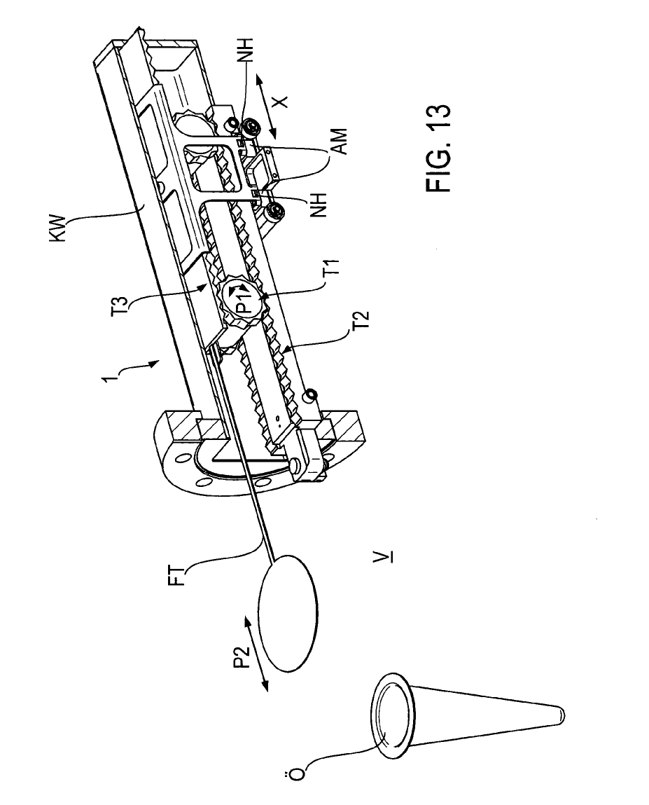

FIG. 13 shows a perspective sectional view an apparatus according to one embodiment of the invention.

The embodiments described below partially coincide, wherein similar or identical parts are referred to using the same reference numerals and having regard to their explanation reference is also made to the respective description of other embodiments in order to avoid repetitions.

FIG. 1 shows a schematic side view of an apparatus 1 for transmission of movement, transmission of torque, transmission of force and/or enabling movement according to one embodiment of the invention. The apparatus 1 is in particular suitable for use in a vacuum, in particular an ultrahigh vacuum.

The apparatus 1 comprises a first part T1 having a plurality of notches 10′, each with a notch base 11′, and a plurality of engagement parts 20′, each having a front end section 21′.

The apparatus 1 also comprises a second part T2 having a plurality of notches 10, each with a notch base 11, and a plurality of engagement parts 20, each having a front end section 21.

The notches 10′ and engagement parts 20′ of the first part T1 together with the notches 10 and engagement parts 20 of the second part T2 form a notch-engagement part mechanism.

In addition to the notch-engagement part mechanism, the apparatus 1 comprises a contact surface F1, which is formed at the first part T1 and a contact surface F2 which is formed at the second part T2.

The two contact surfaces F1, F2 are formed such that the contact surface F1 can roll along the contact surface F2. In this connection reference numeral AR identifies the rolling direction. The first contact surface F1 can be moved to and fro (in a rotatable manner) as indicated by arrow P1 and is for example circular. The second contact surface F2 is fixed and configured flat or planar. In another embodiment, the second contact surface F2 can also be curved.

The contact surface F1 is configured flush with respect to the notch bases 11′ of the first part T1. The contact surface F2 is configured flush with respect to the front end sections 21 of the second part T2. During a rolling process, the contact surface F1 is temporarily aligned at least approximately flush with respect to the front end sections 21 of the second part T2 and, during a rolling process, the contact surface F2 is temporarily aligned at least approximately flush with respect to the notch bases 11′ of the first part T1.

The notch bases 11′ of the first part T1 and the front end sections 21 of the second part T2 are formed for expediently alternating contacting operative connection to one another.

Moreover, a side section SF for lateral guidance of the engagement parts 20′ of the first part T1 is provided at the contact surface F2, wherein the side section SF is exposed by the notches 10 of the second part T2.

FIG. 2 shows an enlarged schematic representation of a part of the apparatus 1 of FIG. 1, during which a notch base 11′ of the first part T1 and a front end section 21 of the second part T2 form a contacting operative connection.

FIG. 3 shows an enlarged schematic representation of a part of the apparatus 1 of FIG. 1, with a front end section 21′ of the first part T1 and a notch base 11 of the second part T2 being spaced apart from one another by a distance a and thus do not form a contacting operative connection, even though the corresponding engagement part 20′ of the first part T1 is positioned as completely as possible in a corresponding notch 10 of the second part T2.

Consequently, the apparatus 1 shown in FIGS. 1 to 3 is configured such that only the notch bases 11′ of the first part T1 can form a contacting operative connection with the front end sections 21 of the second part T2, whereas the front end sections 21′ of the first part T1 and the notch bases 11 of the second part T2 do not form a contacting operative connection and thus remain spaced apart from one another, even if a corresponding engagement part 20′ of the first part T1 enters into a corresponding notch 10 of the second part T2 as completely as possible. The notch-engagement part mechanism is thus formed such that a contacting operative connection of a notch base-front end section pair 11′, 21 transitions indirectly or directly into a notch base-front end section pair 11, 21′, whereas are non-contacting even in the case of an as complete as possible entering or vice versa, while there is always contact between the contact surfaces F1 and F2 a contact.

FIG. 4 shows a schematic side view of an apparatus 1 in another embodiment of the invention. Since it is sufficient for only the notch bases 11′ of the first part T1 to be able to form a contacting operative connection with the front end sections 21 of the second part T2, the shape, arrangement and/or configuration of the notches 10 and of the engagement part 20′ between the active notch base 11′—front end section 21—engagements can be freely selected. This degree of freedom can, for example, be of interest with respect to optimising the technical production thereof and hence with respect to the price of the apparatus 1, as the shape, arrangement and/or configuration of the freely selectable notches and engagement parts can be ideally adapted to the most favourable production process. For example, the engagement parts 20′ of the first part T1 can have a different contour or shape than those of the engagement parts 20 of the second part T2. Furthermore, the notches 10′ of the first part T1 can have a different contour or shape from those of the notches 10 of the second part T2.

FIG. 5 shows a schematic side view of an apparatus 1 according to yet another embodiment of the invention. The first part T1 comprises engagement parts 20′ and notches 10′ each having two differently configured edge sections FA1′ and FA2′. The second part T2 comprises engagement parts 20 and notches 10, which also each have two differently configured edge sections FA1 and FA2.

FIG. 6 shows a side view of an apparatus 1 according to yet another embodiment of the invention, whereas FIGS. 7 and 8 show a perspective view of the apparatus 1 of FIG. 6. FIG. 9 shows an enlarged perspective representation of a part of the apparatus 1 of FIGS. 6 to 8. For reasons of clarity, the references numerals for the notches and engagement parts have been omitted from the FIGS. 6 to 12.

With reference to FIGS. 6 to 8, only the left hand part of the apparatus 1 is described. The right hand part of the apparatus 1 is substantially identical so that reference can be made to the description of the left hand part in order to avoid repetitions.

As shown in FIGS. 6 to 9, the left hand part of the apparatus 1 comprises a first contact surface F1 formed at a first part T1, a second contact surface F2 formed at a second part T2, and a third contact surface F3 formed at a third part T3. The first part T1, and thus the first contact surface F1, can be rotated as indicated by arrow P1, whereas the second part T2 is fixed and the third part T3, as indicated by arrow P2, can be displaced to and fro in a transverse or at least quasi-linear direction.

A rolling process can take place along a rolling direction AR1 between the first contact surface F1 and the second contact surface F2 and a rolling process can take place along a rolling direction AR2 between the first contact surface F1 and the third contact surface F3.

The second part T2 comprises a pocket into which a stainless-steel part which forms the second contact surface F2 is inserted. However, the second contact surface F2 can also be formed directly at the second part T2, for example integrally or in one piece.

The first part T1 comprises, at two of its two sides, a plurality of engagement parts 20′ and notches 10′ and the second part T2 comprises, at two of its sides, a plurality of engagement parts 20 and notches 10. The engagement parts 20′ and the notches 10′ of the first part T1 together with the engagement parts 20 and notches 10 of the second part T2 form two notch-engagement part mechanisms between which the contact surfaces F1 and F2 are positioned. The notch-engagement part mechanisms are spaced apart from one another transverse to the rolling direction AR1.

The third part T3 likewise comprises, at two of its sides, a plurality of notches and engagement parts, which can be substantially identically to the notches 10 and engagement parts 20 of the second part T2. The engagement parts 20′ and the notches 10′ of the first part T1 together with the engagement parts and notches of the third part T3 form two notch-engagement part mechanisms between which the contact surfaces F1 and F3 are positioned. The notch-engagement part mechanisms are spaced apart from one another transverse to the rolling direction AR2.

The third part T3 is a functional part FT or is formed to suitably hold and to move a functional part FT indirectly or directly. The functional part FT can, for example, be driven by means of remotely-acting forces, as indicated by arrow P2 and can, for example, be formed as a closure apparatus for closing and opening an opening or as a specimen or substrate transfer apparatus for transporting specimens or substrates.

The functional part FT can be moved by means of the contact surfaces F1, F2 and F3 and by means of the four notch-engagement part mechanisms such that it can be moved in targeted manner from a starting position to a target position, wherein the movement is expediently at least quasi-linear or transverse.

FIG. 10 shows a front view of the apparatus 1 of FIGS. 6 to 9. FIG. 11 shows a sectional view through the first part T1, the second part T2 and the third part T3 of FIGS. 6 to 10, whereas FIG. 12 shows an enlarged representation of the section identified in FIG. 11.

It can again be seen from the front view in FIG. 10 that the pair of contact surfaces F1 and F2 is formed between two notch-engagement part mechanisms and the pair of contact surfaces F1 and F3 is formed between two notch-engagement part mechanisms.

The sectional view of FIG. 11 shows side sections SF, which serve for the lateral guidance of the moveable parts T1 and T3. In particular, the first contact surface F1 comprises, at two of its longitudinal sides, a side section SF inclined with respect to the vertical by about 10° , which tapers upwards in FIG. 11. The third contact surface F3 also comprises, at two of its longitudinal sides, a side section SF inclined with respect to the vertical by about 10° inclined, which tapers downwards in FIG. 11.

As can be seen from FIGS. 11 and 12, the engagement parts 20′ of the first part T1 comprise, at one or more sides, (expediently conically formed) side regions SB inclined by, for example, 20° with respect to the radial direction.

The lateral guidance takes place by a temporary, rolling operative contact between the bevelled engagement parts 20′ of the first part T1 and the bevelled side sections SF of the second part T2 and of the third part T3. The operative contact takes place in accordance with the skew configurations in a discrete kind and manner, i.e. substantially point-like or edge-shaped. The operative contact then expediently takes place when the engagement parts 20′ of the first part T1 are positioned as completely as possible in the notches 10 of the second part T2 and the notches of the third part T3. Thus a lateral linear guide is formed at the longitudinal boundaries of the three contact surfaces F1, F2 and F3 with an opening angle of, for example 10°, which is formed between the 20° inclined guides at the first part T1 minus the 10° inclined guides at the second part T2 and the third part T3.

FIG. 13 shows a perspective sectional view of an apparatus 1 expediently formed according to FIGS. 6 to 12. FIG. 13 in particular shows a so-called linear shutter in a vacuum system, in particular a device for molecular beam epitaxy or for the vapour deposition of an evaporation material on a substrate.

The vacuum system comprises a chamber bounded by a chamber wall KW, wherein only the part of the chamber wall KW shown in FIG. 13 is that which directly surrounds the apparatus 1. The vacuum system further comprises means (not shown) for generating a vacuum V in the chamber, which thus represents a vacuum chamber, and likewise means, also not shown, for heating the chamber. The means for heating the chamber can be positioned inside or outside of the chamber. Reference numeral Ö identifies an evaporator opening which is also positioned in the chamber and thus can be subjected to a vacuum. The functional part FT is formed as a closure part in order to open and to close the evaporator opening.

The apparatus 1 further comprises means for operating AM for moving the functional part FT. The means for operating AM can be moved to and fro in a motorized manner by means of a motor device (not shown) as indicated by arrow X. The functional part FT is then moved to and fro as indicated by arrow P2 which in turn has the result that the first part T1 is rotated to and fro, as indicated by arrow P1, at the fixed part T2. Thus, the functional part FT can be pushed from a starting position (opening Ö open) into a target position (opening closed) or vice versa.

The means for operating AM indirectly or directly moves the functional part FT from the outside through the chamber wall KW without coming into contact with the functional part FT to this end and without requiring a physical penetration of the chamber wall KW to this end. This is achieved in that the means for operating AM works by means of remotely-acting forces, for example magnetic, electromagnetic or electrostatic forces.

The means for operating AM is also formed such that it generates a contact pressure between the contact surfaces F1 and F2 and F1 and F3 and/or a contact pressure between at least one notch base and at least one front end section, which form a contacting operative connection to one another, by means of which the apparatus 1 can be held together. The contact pressure is generated from the outside through the chamber wall KW without requiring a physical penetration of the chamber wall KW to this end. This is again achieved in that that the means for operating AM works by means of remotely-acting forces, for example magnetic, electromagnetic or electrostatic, forces.

The apparatus 1 further comprises emergency holders NH (for example stops, abutments, brackets, bearings, etc.), which hold the apparatus 1 together. The emergency holders NH prevent an excessive loosening of the contact surfaces F1, F2 and F3 and of the notch-engagement part mechanisms due to the means for operating AM which have become detached or which are not working or only partly working, which could, for example, result in blocking, becoming skewed or even falling apart.

The above preferred exemplary embodiments and/or their individual features can be combined with one another in any way desired. The invention is not limited to the above-described preferred exemplary embodiments. Rather, a plurality of variants and modifications is possible, which also make use of the idea underlying the invention and therefore fall within the scope of protection. In particular, the invention also claims protection for the subject matter of the subordinate claims independently of the subject matter of the preceding claims to which they refer.

1. An apparatus for transmission of movement, transmission of torque, transmission of force and/or enabling movement, and suitable for use in a vacuum, comprising:
at least one notch-engagement part mechanism, which is formed by at least one notch and at least one engagement part; and
at least two contact surfaces, with at least one of the contact surfaces being able to roll along the other contact surface.

2. The apparatus according to claim 1, in which the at least one notch-engagement part mechanism is formed laterally with respect to the two contact surfaces, or at least two of the notch-engagement part mechanisms are formed, between which the two contact surfaces are arranged.

3. The apparatus according to claim 1, in which the at least one notch comprises a notch base and the at least one engagement part comprises a front end section.

4. The apparatus according to claim 3, in which the at least one contact surface is formed at least approximately flush with respect to the notch base and the other contact surface is formed at least approximately flush with respect to the front end section.

5. The apparatus according to claim 3, in which, during a rolling process, the at least one contact surface adopts an at least approximately flush alignment with respect to the front end section and, during the rolling process, the other contact surface adopts an at least approximately flush alignment with respect to the notch base.

6. The apparatus according to claim 3, in which the notch base and the front end section are configured to form a contacting operative connection with one another.

7. The apparatus according to claim 3, in which the notch base and the front end section are formed such that they remain spaced apart from one another even if the corresponding engagement part is positioned as completely as possible in the corresponding notch.

8. The apparatus according to claim 1, in which the at least one notch-engagement part mechanism is formed by a plurality of the notches each comprising the notch base and by a plurality of the engagement parts each comprising the front end section.

9. The apparatus according to claim 1, in which the at least one notch-engagement part mechanism is formed such that a contacting operative connection of a notch base-front end section pair is followed by a notch base front end section pair, wherein the notch base and the front end section remain spaced apart from one another even if the corresponding engagement part is positioned as completely as possible in the corresponding notch or vice versa.

10. The apparatus according to claim 1, in which at least one side section is provided at a contact surface for a lateral guidance of the at least one engagement part.

11. The apparatus according to claim 10, in which the at least one side section and the at least one engagement part are bevelled for the lateral guidance.

12. An apparatus according to claim 10, in which the lateral guidance takes place by means of an at least temporary, discrete operative contact between the side section and the at least one engagement part.

13. The apparatus according to claim 10, in which the side section is bevelled at a different angle of skew than the at least one engagement part.

14. The apparatus according to claim 1, in which the at least one contact surface is, at least in sections thereof, curved, and the other contact surface is, at least in sections thereof, flat or the at least two contact surfaces are curved.

15. The apparatus according to claim 1, in which the at least one notch-engagement part mechanism comprises differently configured notches and differently configured engagement parts.

16. The apparatus according to claim 1, in which a functional part is configured to be moved by means of the at least two contact surfaces and by the at least one notch-engagement part mechanism in such a way that it can be moved from a starting position into a target position and vice versa.

17. An apparatus according to claim 16, in which the functional part comprises a closure apparatus for opening and closing an opening or a workpiece transfer apparatus for transferring workpieces.

18. The apparatus according to claim 1, further comprising a means for operating that is designed to generate a contact pressure between the at least two contact surfaces and/or to move the functional part.

19. The apparatus according to claim 18, in which the contact pressure is generated from outside through a chamber wall by means of a remotely-acting force and/or the functional part is moved from outside through a chamber wall by means of a remotely-acting force.

20. The apparatus according to claim 18, in which the apparatus is arranged within a chamber, with the exception of the means for operating, which is arranged outside the chamber in order to carry out a function within the chamber from the outside by means of a remotely-acting force acting through a chamber wall.

21. The apparatus according to claim 1, further comprising at least one emergency holder, which ensures that the at least two contact surfaces and the at least one notch-engagement part mechanism do not become excessively loose.

22. A vacuum system having an apparatus, the apparatus comprising:
at least one notch-engagement part mechanism, which is formed by at least one notch and at least one engagement part; and
at least two contact surfaces, with at least one of the contact surfaces being able to roll along the other contact surface.

23. The vacuum system according to claim 22, further comprising a chamber bound by a chamber wall and means for generating a vacuum in the chamber and/or a heating apparatus for heating the chamber.

24. A vacuum system according to claim 22, in which the vacuum system comprises a device for molecular beam epitaxy and/or a device for vapour-deposition of an evaporating material on a substrate.

25. The apparatus according to claim 6, in which the notch base is formed at a moving part, and the front end section is formed at a fixed part.

26. The apparatus according to claim 7, in which the notch base is formed at a fixed part, and the front end section is formed at a moving part.
